(19) United States
(12) Patent Application Publication
(10) Pub. No.: US 2023/0104507 A1
(43) Pub. Date: Apr. 6, 2023

(54) System and Method for Hyperloop Motion Control and State Estimation

(71) Applicant: Hyperloop Technologies, Inc., Los Angeles, CA (US)

(72) Inventors: Ke Sun, Los Angeles, CA (US); Alexander Joseph Yuen, Los Angeles, CA (US)

(73) Assignee: Hyperloop Technologies, Inc., Los Angeles, CA (US)

(21) Appl. No.: 17/952,749

(22) Filed: Sep. 26, 2022

Related U.S. Application Data
(60) Provisional application No. 63/278,461, filed on Nov. 11, 2021.
(60) Provisional application No. 63/271,530, filed on Oct. 25, 2021.
(60) Provisional application No. 63/253,123, filed on Oct. 6, 2021.

(51) Int. Cl. B61L 27/10; G01B 11/14; G01R 31/40; B61L 25/02; B61L 27/30; B61L 27/70

(52) U.S. Cl. CPC B61L 27/10; G01B 11/14; G01R 31/40; B61L 25/02; B61L 27/30; B61L 27/70

(57) ABSTRACT

A solution is disclosed for state estimation and motion control for a hyperloop vehicle. The solution is configured to generate a state estimation of a hyperloop vehicle while in flight. The state estimation is generated, in part, by real-time sensor data obtained from a sensor system onboard the hyperloop vehicle. Based on the state estimation, a motion execution module is configured to generate a plurality of linearized commands for a plurality of power electronic units in order to control the position and/or orientation of the hyperloop vehicle. The disclosed solution provides for safe and efficient travel using hyperloop vehicles.

### CROSS REFERENCE AND PRIORITY TO RELATED APPLICATIONS

This application claims the benefit of priority to: U.S. Provisional No. 63/253,123 entitled “SYSTEM AND METHOD FOR HYPERLOOP MOTION CONTROL AND STATE ESTIMATION,” filed on Oct. 6, 2021; U.S. Provisional No. 63/271,530 entitled “SYSTEM AND METHOD FOR HYPERLOOP STATE ESTIMATION OF MULTIPLE AXES,” filed on Oct. 25, 2021; and U.S. Provisional No. 63/278,461 entitled “SYSTEM AND METHOD FOR A HYPERLOOP MOTION EXECUTION CONTROLLER,” filed on Nov. 11, 2021.

All the aforementioned applications are hereby incorporated by reference in their entirety.

### BACKGROUND

Hyperloop is a new mode of transportation relying on a pod traveling through a tube having a near-vacuum environment. The pod may be configured to carry passengers, cargo, or a combination thereof. The projected velocity of the bogie may exceed 700 mph (1,127 km/h) in commercialized implementations. A hyperloop bogie may rely on many types of tracks for guidance. For instance, a hyperloop bogie may simply rely on wheels. However, magnetic levitation (“maglev”) is generally favored over traditional wheeled implementations because maglev provides a substantially frictionless means of guidance, levitation, and propulsion. Having maglev coupled with near-vacuum environments provides for high, sustainable velocities of hyperloop pods moving through the tube. Further, the locomotion is extremely power-efficient and environmentally friendly.

While maglev is preferred for some implementations, maglev requires carefully calibrated interactions between the bogie and the track. Magnetic field interactions may be non-linear and may be difficult to calculate in a hyperloop environment due, in part, to the high velocity of the bogie and the attached pod. The problem of properly calibrated maglev operation is further compounded by the required air gaps between the electromagnetic engine and the track. If the air gap is too large, the magnetic field interactions simply cannot generate locomotion. If the air gap is too small, the physical components of the engine will interfere with the track. Therefore, having an optimized air gap is critical to maglev.

In some implementations, the air gap may be as small as fifteen millimeters, which is roughly the thickness of approximately fifteen credit cards stacked on one another. As the hyperloop pod travels along the track, the air gap may require such precise magnetic interactions that a human operator is simply incapable of responding quickly enough to avoid a collision between the engine and the track. A wheeled bogie implementation does not have similar requirements because wheels rely on contact with a surface. As such, those skilled in the art are seeking solutions to ensure a functional, safe air gap is maintained while the hyperloop pod is in-flight. Further, a poorly managed air gap may lead to the destruction of property and even the loss of life.

What is needed is a system and method for hyperloop motion control and state estimation configured for hyperloop vehicles.

### SUMMARY

A solution is disclosed for a hyperloop system configured to provide state estimation and motion control for a hyperloop vehicle. The solution provides for state estimation using motion control for the hyperloop vehicle, wherein a processor receives sensor data providing a plurality of air gap distances between a plurality of electromagnetic assemblies and a plurality of rails. The plurality of electromagnetic assemblies is associated with a plurality of power electronic units, respectively. The processor may generate a state estimation at a first time that comprises a position of the hyperloop vehicle at a second time and an orientation of the hyperloop vehicle at the second time. The second time is subsequent to the first time. The processor further generates a plurality of non-linearized commands associated with the state estimation, wherein the non-linearized commands are configured to position and orient the plurality of electromagnetic assemblies with respect to the plurality of rails.

The processor further linearizes the plurality of non-linearized commands to generate a plurality of linearized commands. The linearized commands are configured for the plurality of power electronic units to control a plurality of electromagnetic fields generated at the plurality of electromagnetic assemblies. The processor further distributes the linearized commands within the plurality of power electronic units. The sensor data may be obtained from an inertial measurement unit system, a laser gap sensor system, or a combination thereof. The sensor data obtained via the inertial measurement unit system and the laser gap sensor system may be fused at the processor. The sensor data may further comprise wayside communication data received from a wayside communication module, that is in communication with a plurality of transponders, a high-speed network, or a combination thereof. The command may be associated with a current value, an air gap value, a voltage value, an electromagnetic force value, or a combination thereof.

The state estimation further comprises a rate of change of position of the hyperloop vehicle, a rate of change of orientation of the hyperloop vehicle, or a combination thereof. Additionally, the processor may detect a fault at the plurality of power electronic units, the plurality of electromagnetic assemblies, or a combination thereof. Further, the processor may update the state estimation based on the detected fault.

A hyperloop system is also disclosed and similarly configured to generate a state estimation and execute motion control for the hyperloop vehicle. The hyperloop system comprises a plurality of power electronic units comprising a plurality of electromagnetic assemblies, respectively. Further, the hyperloop system comprises a memory and a processor.

The processor of the hyperloop system receives sensor data providing a plurality of air gap distances between a plurality of electromagnetic assemblies and a plurality of rails. The processor may generate a state estimation, at a first time, comprising a position of the hyperloop vehicle at a second time and an orientation of the hyperloop vehicle at the second time. The second time is subsequent to the first time. The processor further generates a plurality of non-linearized commands associated with the state estimation, wherein the non-linearized commands are configured to position and orient the plurality of electromagnetic assemblies with respect to the plurality of rails.

The processor further linearizes the plurality of non-linearized commands to generate a plurality of linearized commands. The linearized commands are configured for the plurality of power electronic units to control a plurality of electromagnetic fields generated at the plurality of electromagnetic assemblies. The processor further distributes the linearized commands within the plurality of power electronic units. The sensor data may be obtained from an inertial measurement unit system, a laser gap sensor system, or a combination thereof. The sensor data obtained via the inertial measurement unit system and the laser gap sensor system may be fused at the processor. The sensor data may further comprise wayside communication data received from a wayside communication module, that is in communication with a plurality of transponders, a high-speed network, or a combination thereof. The command may be associated with a current value, an air gap value, a voltage value, an electromagnetic force value, or a combination thereof.

The state estimation further comprises a rate of change of position of the hyperloop vehicle, a rate of change of orientation of the hyperloop vehicle, or a combination thereof. Additionally, the processor may detect a fault at the plurality of power electronic units, the plurality of electromagnetic assemblies, or a combination thereof. Further, the processor may update the state estimation based on the detected fault.

The disclosed solution provides for motion control execution based on a state estimation of a hyperloop vehicle. The solution provides for a processor configured to generate a state estimation, at a first time, based on a plurality of non-linearized commands for a plurality of power electronic units. Further, the state estimation is associated with a second time, wherein the second time is subsequent to the first time. The processor further processes the plurality of non-linearized commands to generate a plurality of linearized commands. The plurality of linearized commands is configured to position and orient the hyperloop vehicle according to the state estimation. The processor is further configured to send the plurality of linearized commands to a plurality of power electronic units.

The plurality of linearized commands is associated with a current value, an air gap value, a voltage value, an electromagnetic force value, or a combination thereof. The processor may further detect a fault and update the linearized commands to address the fault. The plurality of linearized commands is configured as input to a subsequent state estimation.

A hyperloop system is also disclosed. The hyperloop system is configured to provide motion control to a hyperloop vehicle. The hyperloop system comprises a plurality of power electronic units associated with a plurality of electromagnetic assemblies, respectively. The hyperloop system further comprises a memory and a processor. The processor is configured to generate a state estimation, at a first time, based on a plurality of non-linearized commands for a plurality of power electronic units. Further, the state estimation is associated with a second time, wherein the second time is subsequent to the first time. The processor further processes the plurality of non-linearized commands to generate a plurality of linearized commands. The plurality of linearized commands is configured to position and orient the hyperloop vehicle according to the state estimation. The processor is further configured to send the plurality of linearized commands to a plurality of power electronic units.

The plurality of linearized commands is associated with a current value, an air gap value, a voltage value, an electromagnetic force value, or a combination thereof. The processor may further detect a fault and update the linearized commands to address the fault. The plurality of linearized commands is configured as input to a subsequent state estimation.

### BRIEF DESCRIPTION OF DRAWINGS

The accompanying drawings, which are incorporated herein and constitute part of this specification, illustrate exemplary aspects of the claims, and together with the general description given above and the detailed description given below, serve to explain the features of the claims.

FIG. 1 is a block diagram illustrating a track assembly.

FIG. 2A is planar view of a pod assembly and a bogie assembly, shown from a front perspective of a hyperloop vehicle.

FIG. 2B is a planar view of a pod assembly and a bogie assembly, shown from a side perspective of a hyperloop vehicle.

FIG. 2C is a planar view of a pod assembly and a bogie assembly, shown from a side perspective of a hyperloop vehicle.

FIG. 3A is a planar view of an electromagnetic assembly, as shown from a front perspective.

FIG. 3B is planar view of an electromagnetic assembly, as shown from a side perspective.

FIG. 3C is a planar view of a rail, as shown from a side perspective.

FIG. 3D is a planar view of an electromagnetic assembly, as shown from a top perspective.

FIG. 3E is a planar view of an electromagnetic assembly, as shown from a top perspective.

FIG. 3F is a planar view of a rail, as shown from a top perspective.

FIG. 3G is a planar view of a rail, as shown from a front perspective.

FIG. 3H is a planar view of a rail, as shown from a front perspective.

FIG. 4 is a block diagram depicting a hyperloop system configured to provide motion control and state estimation for a hyperloop vehicle.

FIG. 5A is a flowchart depicting a process for providing motion control and state estimation for a hyperloop vehicle using a hyperloop system.

FIG. 5B is a flowchart depicting a process for providing motion control and state estimation for a hyperloop vehicle using a hyperloop system.

FIG. 6 is a block diagram illustrating an example computing device suitable for use with the various aspects described herein.

FIG. 7 is a block diagram illustrating an example server suitable for use with the various aspects described herein.

### DETAILED DESCRIPTION

Various aspects will be described in detail with reference to the accompanying drawings. Wherever possible, the same reference numbers will be used throughout the drawings to refer to the same or like parts. References made to particular examples and implementations are for illustrative purposes, and are not intended to limit the scope of the claims.

A hyperloop vehicle is generally comprised of a hyperloop pod and a hyperloop bogie. Hyperloop pods may be attached to a bogie that has a plurality of electromagnetic engines. An electromagnetic engine may perform guidance, levitation, propulsion, or a combination thereof. Propulsion generally provides locomotion along the track in what one of skill in the art would consider the x-axis. Levitation and guidance generally provide calibration of the pod in five axes viz. y, z, roll, pitch, and yaw such that the pod may properly traverse along the track in the x-axis. Designers generally favor minimizing guidance events for the hyperloop vehicle because such guidance events require high levels of power to generate force. Therefore, balancing the hyperloop vehicle such that levitation is maintained at low power is desirable. For example, if the nose of the pod pitches too high, the electromagnetic engines may collide with the track, thus causing harm to property and passengers. Similarly, if the pod rotates about the z-axis to an excessive degree, the pod may collide with the track, causing damage to property as well as loss of life. In short, the hyperloop vehicle requires careful calibration in order to safely and reliably transport passengers and/or cargo.

Providing effective levitation and guidance is a non-trivial problem because a hyperloop pod may have a longitudinal size that requires several electromagnetic engines to operate in coordination. Such coordination ensures the hyperloop bogie and the attached pod travel with the desired air gap distance (e.g., fifteen millimeters). In the event that one engine exhibits aberrant behavior, the remaining engines may need to compensate in order to sustain safe, efficient locomotion. While the various engines may be similarly designed, each may have a unique variance that also needs to be accounted for by a levitation and guidance algorithm designed to maintain a particular position and orientation during flight.

To further compound the problem of levitation and guidance, magnetic fields and electromagnetic forces tend to have non-linear behavior. For instance, the flux density of a rail may be affected by the distance to the electromagnetic source, the velocity of the electromagnetic engine relative to the rail as well as the orientation of the electromagnetic source relative to the rail. In short, managing a plurality of electromagnetic engines with a small air gap requires a solution to ensure that electromagnetic interactions achieve the desired results without introducing undesired results (which often include damage to property and loss of life).

A solution to the above-stated problems is a system and method for hyperloop vehicle levitation and guidance control that utilizes state estimation to provide guidance-related information to a motion controller configured to manage a plurality of electromagnetic engines disposed throughout the hyperloop bogie. The state of the hyperloop vehicle may be generally defined as a five-axis orientation (i.e., y, z, pitch, roll, yaw) of the hyperloop vehicle. Since the state of the hyperloop vehicle constantly changes, the motion controller may in turn continuously update the commands sent to the electromagnetic engines such that safe, efficient flight of the hyperloop vehicle is achieved as well as maintained throughout flight. In other words, the motion controller generates work to maintain guidance.

To determine the current state of the hyperloop vehicle, the disclosed solution may rely on a number of sensors disposed throughout the hyperloop bogie and pod. For instance, an inertial measurement unit (“IMU”) may operate to determine the orientation (or state) of the bogie and pod. Other sensors may be utilized in addition to an IMU, including laser sensors, cameras, accelerometers, electromagnetic coils, Hall effect sensors, etc.

In sum, the disclosed solution enables a hyperloop vehicle to traverse longitudinally along a track without collision with the track (or other objects). Further, the disclosed solution enables more energy-efficient operation of the plurality of electromagnetic engines. Still further, the disclosed solution provides for smoother rides for passengers and cargo. Yet further, the disclosed solution provides for thermally efficient operation of the plurality of electromagnetic engines.

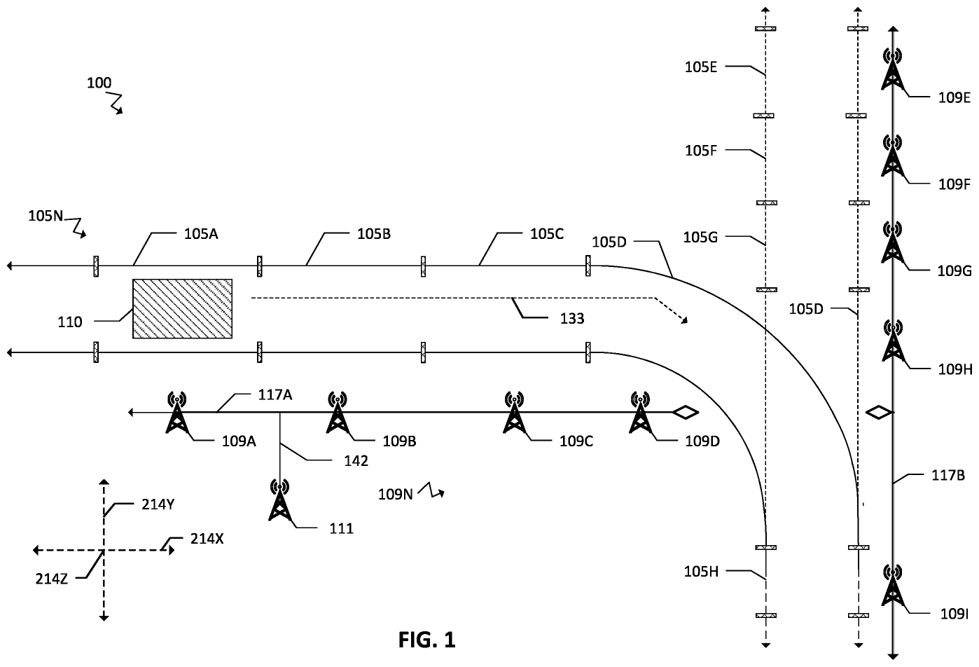

FIG. 1 illustrates a block diagram of a track assembly 100 with a hyperloop vehicle 110. A plurality of axes is shown to orient the reader viz. a first axis 214X, a second axis 214Y, and a third axis 214Z.

A plurality of tube sections 105N has a first tube section 105A, a second tube section 105B, a third tube section 105C, a fourth tube section 105D, a fifth tube section 105E, a sixth tube section 105F, a seventh tube section 105G, an eighth tube section 105H, and a ninth tube section 105I. The plurality of tube sections 105N are generally assembled together on the site of the track assembly 100. In one aspect, the plurality of tube sections 105N may be supported by pylons or other superstructures that elevate the tube above ground level. Such support structures are commonly referred to as “hyperstructure.” In another aspect, the plurality of tube sections 105N may have a near-vacuum environment such that the hyperloop vehicle 110 may operate with reduced air resistance. However, low air resistance enables high velocities that increase risk to passengers and/or cargo, hence the need for the disclosed solution.

The plurality of tube sections 105N has a track (not shown) disposed therein. In one aspect, the track may be made of laminated steel that is configured to enable maglev locomotion of the hyperloop vehicle 110. Other ferromagnetic materials may be similarly utilized.

The bogie assembly 220 possesses the necessary systems to provide locomotion that is safe, energy efficient, and reliable. For instance, the bogie assembly 220 may have propulsion systems that generate force by use of electromagnetic engines disposed near the rails of the track. The bogie assembly 220 may have additional systems including braking systems, levitation systems, guidance systems, lighting systems, sensor systems, fault tolerance systems, passenger management systems, cargo management systems, navigation systems, communication systems, emergency systems, maintenance systems, etc.

The hyperloop vehicle 110 comprises a pod assembly, that is configured to provide transportation of cargo, passengers, or a combination thereof. The pod assembly may have some of the systems of the bogie assembly (and vice versa). For the purposes of this disclosure, the hyperloop vehicle 110 will be generally referred to for both the bogie assembly and the pod assembly. One of skill in the art will appreciate that the internal configuration of the hyperloop vehicle 110 may vary depending on the operating environment of the hyperloop implementation.

A direction of travel 133 is shown to indicate the direction along which the hyperloop vehicle 110 is traveling. As shown, the hyperloop vehicle 110 is traveling along the axis 214X toward the tube section 105D at which point the hyperloop vehicle 110 will turn toward the section 105H. Thus, the direction of travel 133 transitions to become substantially parallel with the axis 214Y. The hyperloop vehicle 110 is configured to turn at high speeds; if a second hyperloop vehicle is traveling through the tube sections 105E, 105F, 105G, the hyperloop vehicle 110 may need to have such information in order to avoid a collision with the second hyperloop vehicle. The state estimation disclosed herein may anticipate a collision at a given time. In addition, the motion control provided herein may be utilized to avoid the collision based on the state estimation. Thus, a second hyperloop vehicle can be avoided with the aid of the disclosed solution.

A plurality of transponders 109N are disposed at or near the plurality of tube sections 105N. The plurality of transponders 109N comprises a first transponder 109A, a second transponder 109B, a third transponder 109C, a fourth transponder 109D, a fifth transponder 109E, a sixth transponder 109F, a seventh transponder 109G, an eighth transponder 109H, and a ninth transponder 109I. The transponders 109A, 109B, 109C, 109D are interconnected by a link 117A. The transponders 109E, 109F, 109G, 109H, 109I are connected via a link 117B. In one aspect, the links 117A, 117B may be connected such that the plurality of transponders 109N are interconnected and understood be one network (or subnetwork). For clarity, a diamond symbol is shown to depict that the links 117A, 117B are interconnected.

A transponder is generally configured to communicate with the hyperloop vehicle 110 when in proximity to the transponder. Information may be sent from the transponder to the hyperloop vehicle 110 or vice versa, depending on operating conditions and parameters. For instance, the hyperloop vehicle 110 is shown as passing the transponder 109A in the instant view. The hyperloop vehicle 110 will pass the transponder 109B when traveling through the tube section 105B. In one aspect, the plurality of transponders 109N may correspond to each of the plurality of tube sections 105N. For instance, the tube section 105A corresponds to the transponder 109A. In one aspect, the tube section 105A may have the transponder 109A attached thereto and deployed as part of the tube section 105A.

A high-speed network 111 is available at or near the track assembly 100 such that the elements within the track assembly 100 may communicate with other elements in the track assembly 100. The high-speed network 111 is connected to the plurality of transponders 109N via a link 142. In one aspect, the plurality of transponders 109N may provide access to information communicated by the high-speed network 111. The high-speed network 111 may be a combination of wired and wireless communication means, in one aspect. In one aspect, the high-speed network 111 may be 5G. In another aspect, the high-speed network 111 may be WIFI. In general, the hyperloop vehicle 110 may be in communication with the high-speed network 111 as well as the plurality of transponders 109N, wherein each communication means has an assigned role. For instance, the plurality of transponders 109N may be charged with delivering short, critical messages whereas the high-speed network 111 may be charged with delivering long, less-critical messages.

The hyperloop vehicle 110 may communicate with a fleet management center (not shown) via the high-speed network 111 in order to communicate fleet-management data. For example, a message may be sent to the hyperloop vehicle 110 to instruct the hyperloop vehicle 110 to enter a stable for service. Such messages provide yet another source of data for the disclosed solution to enable guidance control of the hyperloop vehicle 110. For instance, the hyperloop vehicle 110 may require messages to guide the hyperloop vehicle through a non-moving switch (e.g., at or near the tube section 105D).

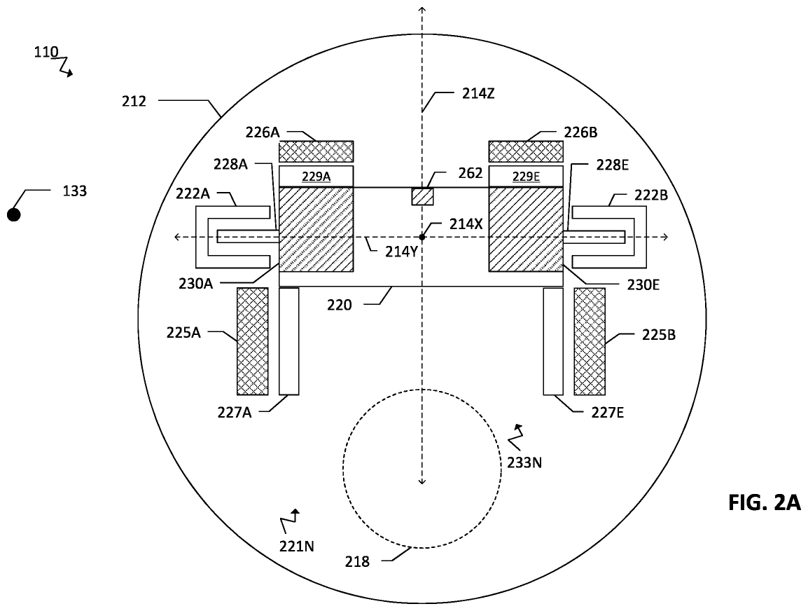

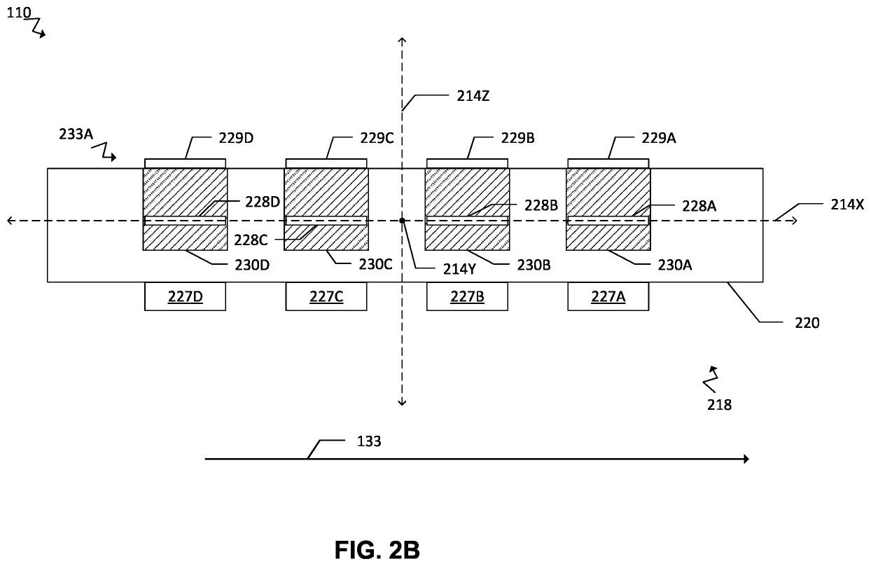

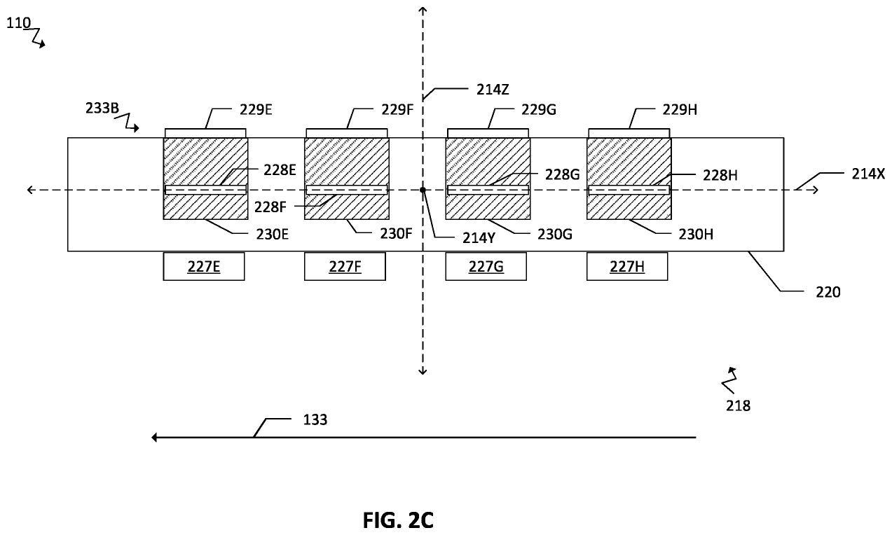

FIG. 2A is a planar view of a pod assembly 218 and a bogie assembly 220, shown from a front perspective of the hyperloop vehicle 110. The pod assembly 218 is removed from the instant view to provide better clarity. However, the pod assembly 218 is positioned below the bogie assembly 220 along the axis 218X for illustrative purposes. One of skill in the art may refer to a bogie assembly above the pod assembly as a “toplev” configuration, which is derived from maglev to indicate that the bogie assembly 220 is above the pod assembly 218. In one aspect, the pod assembly 218 may be generally configured to carry passengers. Depending on operating conditions, the pod assembly 218 may be generally configured to carry cargo. The pod assembly 218 is depicted as cylindrical, but one of skill in the art will appreciate that the design of the pod assembly 218 may be any shape operable to fit inside a low-pressure tube.

The pod assembly 218 is connected to the bogie assembly 220. The bogie assembly 220 is generally configured to provide locomotion to the pod assembly 218 within a tube assembly 212. In one aspect, the tube assembly 212 may correspond to one of the tube sections within the plurality of tube sections 105N. The bogie assembly 220 may contain any number of electronic and mechanical systems. As shown, the bogie assembly 220 contains a first power electronic unit (“PEU”) 230A and a second PEU 230E. The PEUs 230A, 230E are configured to provide propulsion, levitation, and/or guidance to the hyperloop vehicle 110 by use of electromagnetic assemblies. A plurality of PEUs 233N is comprised of the first PEU 230A, the second PEU 230E, and six additional PEUs (not shown in the instant view). One of skill in the art will appreciate that the number of PEUs may be adjusted for various operating environments and hyperloop vehicle configurations.

The tube assembly 212 has a plurality of rails 221N comprising a first rail 222A, a second rail 222B, a third rail 225A, a fourth rail 225B, a fifth rail 226A, and a sixth rail 226B. In one aspect, the tube assembly 212 may contain an environment comprising air. Further, the air may be at a pressure lower than one atmosphere. In one aspect, the environment may at near-vacuum pressure.

The plurality of rails 221N are maglev rails. In one aspect, the plurality of rails 221N may be comprised of steel, which may be laminated in some implementations. The bogie assembly 220 is generally configured to levitate, propel, and guide the hyperloop vehicle 110 via the plurality of rails 221N.

Propulsion may be achieved by interposing a first electromagnetic assembly 228A inside the rail 222A and a second electromagnetic assembly 228E inside the rail 222B. The electromagnetic assemblies 228A, 228E are configured to generate an electromagnetic field configured to penetrate the rails 222A, 222B, respectively, in order to create electromagnetic force along the axis 214X. The electromagnetic assembly 228A may be part of and/or connected to the PEU 230A. Likewise, the electromagnetic assembly 228E may be part of and/or connected to the PEU 230E. In one aspect, the rails 222A, 222B may be composed of steel. The rails 222A, 222B and the electromagnetic assemblies 228A, 228E have attractive and/or repulsive magnetic forces between one another.

Electromagnetic assemblies (e.g., the electromagnetic assemblies 228A, 228E) may freely move along or about a plurality of axes. As shown, the bogie assembly 220 travels longitudinally along the first axis 214X. Further, the bogie assembly 220 travels horizontally along the second axis 214Y. Still further, the bogie assembly 220 travels vertically along the third axis 214Z. One of skill in the art will appreciate that the axis 214X is projected both toward the viewer and away from the viewer. Five-axis control is performed with respect to guidance and levitation. Specifically, the electromagnetic assemblies 229A, 229E correspond to levitation of the hyperloop vehicle 110. Whereas, the electromagnetic assemblies 227A, 227E correspond to guidance of the hyperloop vehicle. In aeronautical terms, the three axes 214X, 214Y, 214Z may correspond to the principal rotational axes of an aircraft i.e., roll, pitch, and yaw. One of skill in the art will appreciate the difficulty in maintaining balance among the electromagnetic assemblies 229A, 229E, 227A, 227E with respect to the rails 226A, 226B, 225A, 225B. For example, a clockwise rotation about the axis 214X may cause the electromagnetic assembly 228A to approach the top of the rail 222A thus causing the electromagnetic assembly 228E to approach the bottom of the rail 222B. In other words, rotational movements of the hyperloop vehicle 110 may lead to collisions between the electromagnetic assemblies 228A, 228E with the rails 222A, 222B—a situation that may lead to damage of property and even the loss of life.

A first electromagnetic assembly 227A and a second electromagnetic assembly 227E are disposed on the lateral sides of the bogie assembly 220. Further, the electromagnetic assemblies 227A, 227E are positioned near the first rail 225A and the second rail 225B, respectively. The electromagnetic assemblies 227A, 227E may, in one aspect, be substantially similar to the electromagnetic assemblies 228A, 228E as well as a first electromagnetic assembly 229A and a second electromagnetic assembly 229E. The electromagnetic assemblies 227A, 227B, 227C, 227D, 227E, 227F, 227G, 227H may, in one aspect, be combined such that the plurality act to create yaw motion via coordination.

The first electromagnetic assembly 229A and the second electromagnetic assembly 229E are disposed on the dorsal side of the bogie assembly 220. Further, the electromagnetic assemblies 229A, 229E are positioned near the first rail 226A and the second rail 226B, respectively. The electromagnetic assemblies 229A, 229E may be substantially similar to the electromagnetic assemblies 227A, 227E, 228A, 228E, mutatis mutandis. The electromagnetic assemblies 229A, 229E electromagnetically interact with the rails 226A, 226B in order to generate electromagnetic force to provide levitation in the direction of the axis 214Z. Further, the generated electromagnetic force may provide both roll and pitch control for the hyperloop vehicle 110.

A sensor system 262 is disposed in the hyperloop bogie assembly 220. The sensor system 262 may be one or more sensors that are configured to obtain measurements related to position, speed, temperature, battery levels, current, line-of-sight, orientation, rotation, air pressure, distance, specific force, angular rate, power draw, mass, dimensions, etc. In one aspect, the sensor system 262 may have a laser-based sensor configured to measure the distance between two objects. For example, the sensor system 262 may be configured to provide a measurement of the distance between the rail 222A and the electromagnetic assembly 228A. Such a measurement may inform the calculation of the air gap, as described above. In another aspect, the sensor system 262 comprises an inertial measurement unit that may be a combination of accelerometers, gyroscopes, and magnetometers. For example, the sensor system 262 may be configured to detect a rotational force operating about the axis 214Y.

FIG. 2B is a planar view of the pod assembly 218 and the bogie assembly 220, shown from a side perspective of the hyperloop vehicle 110. The plurality of rails 221N are not shown in order to provide better clarity. The bogie assembly 220 houses a plurality of PEUs 233A as shown in the instant view. The plurality of PEUs 233A form part of the plurality of PEUs 233N as described above. The first PEU 230A is a member of the plurality of PEUs 233A; the PEU 230A may be disposed toward the front of the bogie assembly 220. Further, the plurality of PEUs 233A further comprises a second PEU 230B, a third PEU 230C, and a fourth PEU 230D.

The PEU 230B comprises a first electromagnetic assembly 227B, a second electromagnetic assembly 228B, and a third electromagnetic assembly 229B. The PEU 230C comprises a first electromagnetic assembly 227C, a second electromagnetic assembly 228C, and a third electromagnetic assembly 229C. The PEU 230D comprises a first electromagnetic assembly 227D, a second electromagnetic assembly 228D, and a third electromagnetic assembly 229D. One of skill in the art will appreciate that the PEUs 230A, 230B, 230C, 230D may be substantially similarly configured as part of the disclosed solution, given that the PEUs 230A, 230B, 230C, 230D generally coordinate to achieve guidance control.

The bogie assembly 220 is configured to traverse along the axes 214X, 214Y, 214Z as well as rotate about the axes 214X, 214Y, 214Z. Given the high-velocity nature of hyperloop locomotion, one of skill in the art will appreciate the difficulty in managing the position of the electromagnetic assemblies 228A, 228B, 228C, 228D while moving through the rails 222A, 222B. For example, if the rails 222A, 222B are inadequately calibrated during installation, the electromagnetic assembly 228A may be attracted to the bottom face of the rail 222A causing the electromagnetic assembly 228D to rise toward the top face of the rail 222A. Therefore, slight deviations in the rails 222A, 222B may introduce yet another factor that the hyperloop vehicle 110 may need to address in order to avoid contact between the rails 222A, 222B and the electromagnetic assemblies 228A, 228B, 228C, 228D. As such, in one aspect, installation faults may be detected via the disclosed solution as part of the normal operations of the hyperloop vehicle 110. For instance, the sensor system 262 may detect installation faults as input into algorithms configured to position and orient the hyperloop vehicle 110. Such detection may inform subsequent operations of the hyperloop vehicle 110 operating in proximity to the previously detected fault.

The pod assembly 218 and the bogie assembly 220 comprise many other systems and subsystems that are beyond the scope of the instant disclosure. However, one of skill in the art will appreciate that the pod assembly 218 may contain, for example, climate control systems, autonomous navigation systems, radio communication systems, life support systems, additional sensors, safety systems, cargo-related equipment, luggage storage, entertainment systems, Internet access systems, etc. Likewise, the bogie assembly 220 may contain, for example, pod-to-pod traffic control systems, signaling systems, headlight systems, line-of-sight systems, braking systems, safety systems, power management systems, power charging systems, etc.

FIG. 2C is a planar view of the pod assembly 218 and the bogie assembly 220, shown from a side perspective of the hyperloop vehicle 110. A plurality of PEUs 233B is comprised of the first PEU 230E, a second PEU 230F, a third PEU 230G, and a fourth PEU 230H. The plurality of PEUs 233B are part of the plurality of PEUs 233N. The PEU 230F has a first electromagnetic assembly 227F, a second electromagnetic assembly 228F, and a third electromagnetic assembly 229F. The PEU 230G has a first electromagnetic assembly 227G, a second electromagnetic assembly 228G, and a third electromagnetic assembly 229G. The PEU 230H has a first electromagnetic assembly 227H, a second electromagnetic assembly 228H, and a third electromagnetic assembly 229H.

One of skill in the art will appreciate that the plurality of electromagnetic assemblies 233A, 233B may be substantially similar in design, configuration, and function. In one aspect, the individual PEUs (e.g., the PEU 230E) may be combined with other PEUs within the pluralities of PEUs 233A, 233B, 233N. Likewise, additional PEUs may be added to any of the pluralities of PEUs 233A, 233B, 233N. A plurality of electromagnetic assemblies 279N is formed by the electromagnetic assemblies 227A, 227B, 227C, 227D, 227E, 227F, 227G, 227H, 228A, 228B, 228C, 228D, 228E, 228F, 228G, 228H, 229A, 229B, 229C, 229D, 229E, 229F, 229G, 229H.

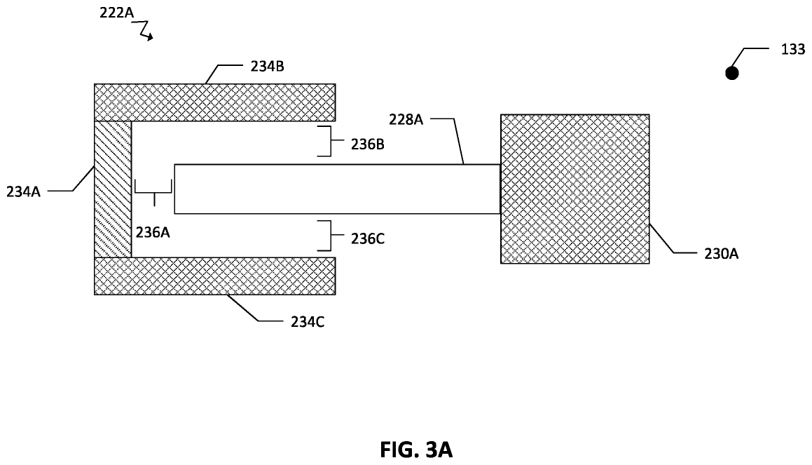

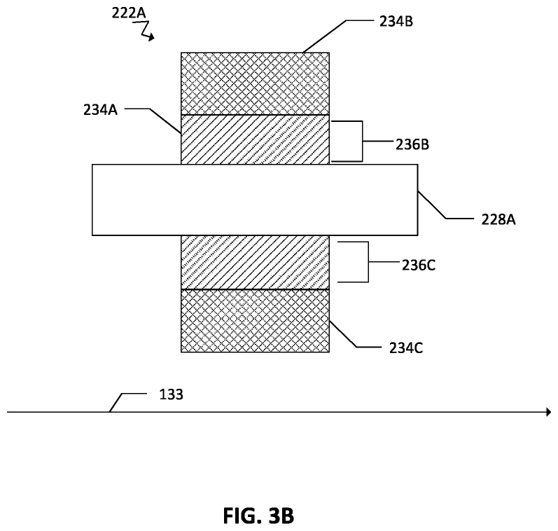

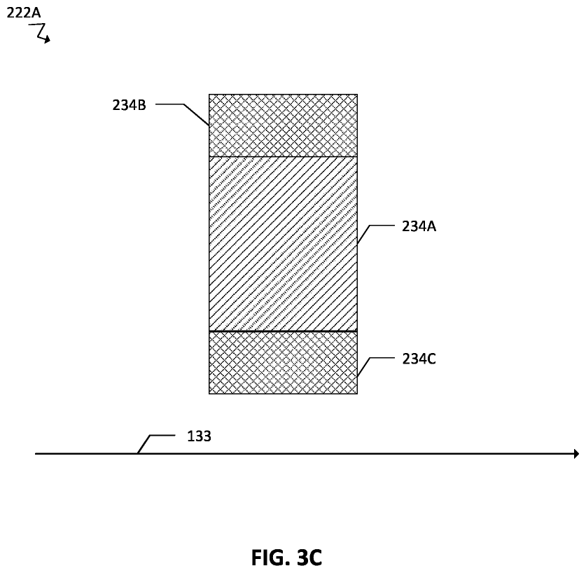

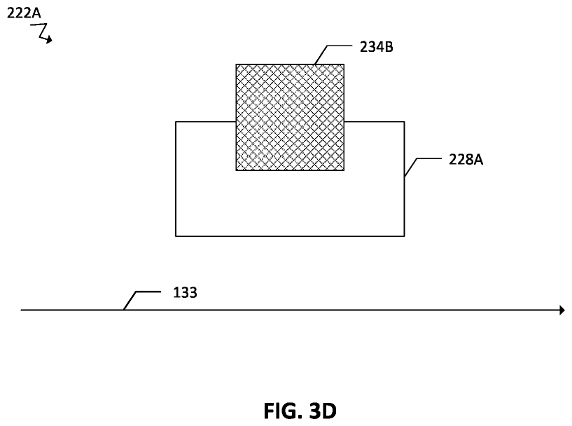

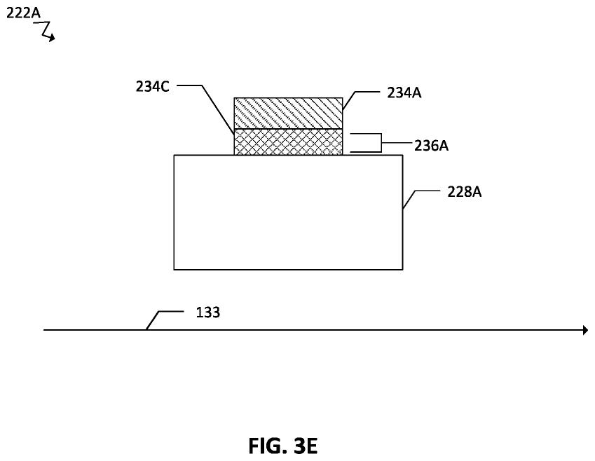

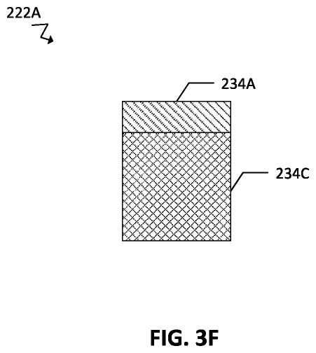

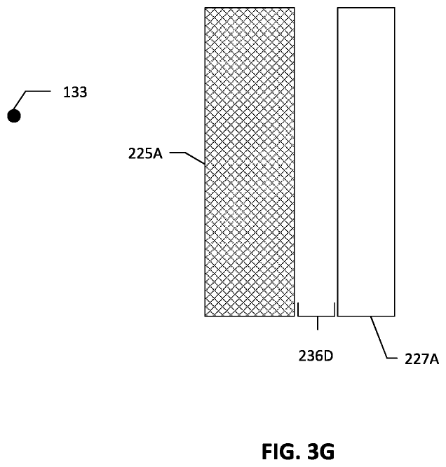

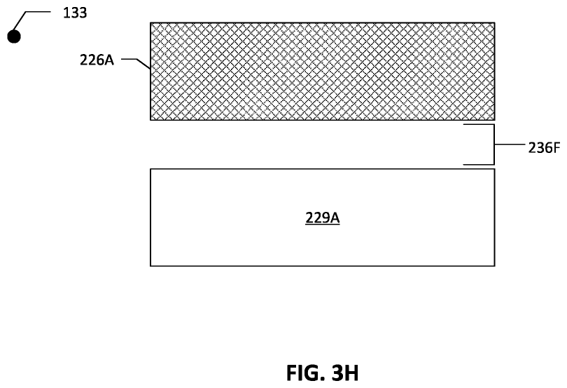

FIG. 3A is a planar view of the electromagnetic assembly 228A, as shown from a front perspective. The rail 222A comprises a first rail section 234A, a second rail section 234B, and a third rail section 234C. The rail 222A, in one aspect, may be laminated steel. The electromagnetic assembly 228A comprises a lateral air gap 236A, a dorsal air gap 236B, and a ventral air gap 236C. The air gaps 236A, 236B, 236C are a distance generally present to provide substantially frictionless movement of the electromagnetic assembly 228A as the bogie assembly 220 travels, via maglev, along the rail 222A. In some commercialized implementations, the air gaps 236A, 236B, 236C may be as small as fifteen millimeters in order to maintain the attractive and/or repulsive magnetic forces necessary for substantially frictionless locomotion. One of skill in the art will appreciate that a collision risk exists between the rail 222A and the electromagnetic assembly 228A—therefore emphasizing the need for the disclosed solution.

FIG. 3B is planar view of an electromagnetic assembly 228A, as shown from a side perspective. The lateral air gap 236A is obstructed in the instant view. Further, the PEU 230A is omitted in the instant view.

One of skill in the art will appreciate the difficultly of maintaining the necessary distance between the rail 222A and the electromagnetic assembly 228A while the bogie assembly 220 is traveling at high velocity. Any subtle change to one air gap may affect at least one other air gap. The problem is further complicated by having several electromagnetic assemblies (e.g., the electromagnetic assembly 228A), each with their own respective air gaps, all of which may need to be at or near fifteen millimeters. Therefore, the plurality of PEUs 233N may be required to act in concert such that the necessary air gap is maintained. To further compound the problem, installation tolerances may have been exceeded (or unsatisfied) during installation of the rail 222A. As such, the hyperloop bogie 220 may be configured to account for deviations in the alignment of the rail 222A while the hyperloop vehicle 110 is in flight. Such fault detection may be configured to support state estimation determinations during subsequent operations of the disclosed solution.

FIG. 3C is a planar view of the rail 222A, as shown from a side perspective. The electromagnetic assembly 228A has been omitted for clarity.

FIG. 3D is a planar view of the electromagnetic assembly 228A, as shown from a top perspective. The electromagnetic assembly 228A is depicted as being positioned within the C-channel of the rail 222A.

FIG. 3E is a planar view of the electromagnetic assembly 228A, as shown from a top perspective. The rail section 234B has been omitted in the instant figure for clarity.

FIG. 3F is a planar view of the rail 222A, as shown from a top perspective. For purposes of clarity, the electromagnetic assembly 228A is not shown. Further, no air gaps are depicted in the instant figure.

FIG. 3G is a planar view of the rail 225A, as shown from a front perspective. A distance 236D is shown that is substantially similar to the air gaps 236A, 236B, 236C. FIG. 3H is a planar view of the rail 226A, as shown from a front perspective. An air gap distance of 236F is shown that is substantially similar to the air gaps 236A, 236B, 236C, 236D, mutatis mutandis.

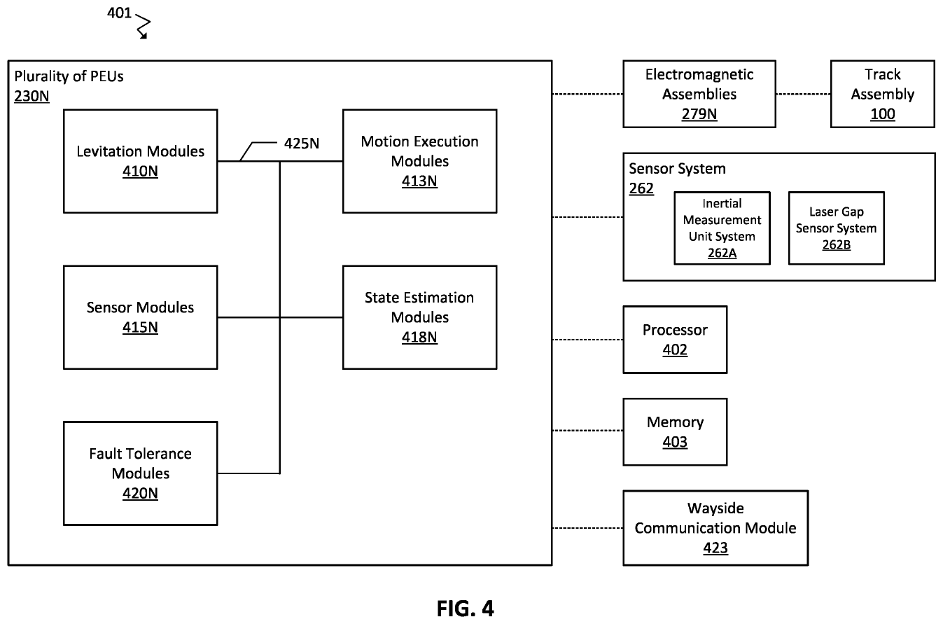

FIG. 4 is a block diagram depicting a hyperloop system 401 configured to provide motion control and state estimation for the hyperloop vehicle 110. At a high level, the hyperloop system 401 is generally configured to generate a state estimation which may be utilized to command the plurality of PEUs 233N. A state estimation is an orientation and/or position of the hyperloop vehicle 110 at a given point in time. For example, the axes 214X, 214Y, 214Z may be utilized to determine the absolute position of the hyperloop vehicle 110 with respect to a fixed position in the tube 212 (e.g., the rail 226A). Likewise, the roll, pitch, and yaw may be represented as rotational values about a fixed axis associated with the hyperloop vehicle 110. For example, the roll, pitch, and yaw may be measured in radian and/or degrees about the axes 214X, 214Y, 214Z which may extend from the center of gravity of the hyperloop vehicle 110.

State estimation is generally utilized to generate estimations of the position (of the hyperloop vehicle 110) for a plurality of motion execution modules 413N. The plurality of motion execution modules 413N are configured to generate commands for the plurality of electromagnetic assemblies 279N. The hyperloop vehicle 110 may have several PEUs (e.g., the plurality of PEUs 233N). As such, the individual PEUs may affect one another inadvertently (and sometimes intentionally). For example, the PEU 230A may generate an electromagnetic force that biases the rail 222A. Further, the PEU 230B may be relying on a particular flux density to generate the required electromagnetic force for the guidance commands invoked at the PEU 230B. However, the PEU 230A has increased the flux density, thus causing the PEU 230B to fail at generating the requested electromagnetic force. Further, the PEU 230B may continue to provide ineffective commands due to the fact that the PEUs 230A, 230B operate substantially independently. However, the hyperloop system 401 provides for state estimation and motion control such that the desired guidance commands are sent to the plurality of electromagnetic assemblies 279N in a manner that provides increases in energy efficiency, safety, control, passenger comfort, operating velocities, operating accelerations, commercial viability of hyperloop, etc.

For maglev locomotion, the hyperloop vehicle 110 is generally proximate to the track assembly 100 (e.g., comprising the rail 224A). In some implementations, the hyperloop vehicle 110 may be in communication with the plurality of wayside transponders 109N and the high-speed network 111. Such communication may, in certain circumstances, provide high-level or coarse information regarding the position of the hyperloop vehicle 110 with respect to the track assembly 100. For example, the plurality of wayside transponders 109N may provide information to the hyperloop vehicle 110, indicating that the hyperloop vehicle 110 is located within the curve present in the tube section 105D. The state estimation provided herein may, as necessary, account for the curvature indicated by installation plans and as communicated by the plurality of transponders 109N.

The plurality of PEUs 233N has a plurality of levitation modules 410N, the plurality of motion execution modules 413N, a plurality of sensor modules 415N, a plurality of state estimation modules 418N, and a plurality of fault tolerance modules 420N. The pluralities of modules 410N, 413N, 415N, 418N, 420N may have a module disposed in each of the plurality of PEUs 233N such that each of the PEUs in the plurality of PEUs 233N may operate substantially independently in order to provide the necessary real-time guidance, propulsion, and levitation. The plurality of PEUs 233N vote according to a voting algorithm in order to generate a consensus of operations within the plurality of PEUs 233N. One of skill in the art will recall that individual PEUs affect one another when operating during flight of the hyperloop vehicle 110.

A plurality of links 425N are present between the plurality of levitation modules 410N, the plurality of motion execution modules 413N, the plurality of sensor modules 415N, the plurality of state estimation modules 418N, and the plurality of fault tolerance modules 420N. Each of the PEUs within the plurality of PEUs 233N may have a respective instance of a link derived from the plurality of links 425N. One of skill in the art will appreciate that each of the PEUs (e.g., the PEU 230A) within the plurality of PEUs 233N has a link which connects each of the modules (e.g., a levitation module from the plurality of levitation modules 410N) within the PEU (e.g., the PEU 230A). In one aspect, the plurality of links 425N may be a logical connection between the various modules 410N, 413N, 415N, 418N, 420N in a software-based configuration. For example, the modules 410N, 413N, 415N, 418N, 420N may be compiled or linked together to form one software module. In another aspect, the plurality of links 425N may be a physical connection between the various modules 410N, 413N, 415N, 418N, 420N, which may be embodied in hardware, software, or a combination thereof.

The hyperloop system 401 further comprises a processor 402 and a memory 403. The processor 402 may be a shared processor which is utilized by other systems, modules, etc. within the disclosed solution. For example, the processor 402 may be configured as a general-purpose processor (e.g., x86, ARM, etc.) that is configured to manage operations from many disparate systems, including the hyperloop system 401. In another aspect, the processor 402 may be an abstraction because any of the modules, systems, and/or components disclosed herein may have a local processor (or controller) that handles aspects of the hyperloop system 401 (e.g., ASICs, FPGAs, etc.).

The memory 403 is generally configured to store and retrieve information. The memory 403 may be comprised of volatile memory, non-volatile memory, or a combination thereof. The memory 403 may be closely coupled to the processor 402, in one aspect. For example, the memory 403 may be a cache that is co-located with the processor 402. As with the processor 402, the memory 403 may, in one aspect, be an abstraction wherein the modules, systems, and/or components each have a memory that acts in concert across the hyperloop system 401.

For purposes of explanation, an instance of a module from the various pluralities of modules 410N, 413N, 415N, 418N, 420N will be disclosed as a levitation module 410A, a motion execution module 413A, a sensor module 415A, a state estimation module 418A, and a fault tolerance module 420A. Further, an instance of the plurality of links 425N may be a link 425A. The aforementioned modules 410A, 413A, 415A, 418A, 420A and the link 425A are disposed within the PEU 230A for purposes of explanation.

The levitation module 410A is generally configured to command the plurality of electromagnetic assemblies 279N. In one aspect, the levitation module 410A may address the electromagnetic assemblies 227A, 228A, 229A. For example, the levitation module 410A may receive a current value (e.g., ten amps) and may excite the electromagnetic assembly 228A. In one aspect, the plurality of PEUs 233N may further adjust the current amount to account for subsystems within a given PEU. For example, the electromagnetic assembly 228A may have more than one electromagnetic assembly contained therein (e.g., three magnetic coils).

The motion execution module 413A is generally configured to receive a state estimation and generate a plurality of commands that may, in turn, be sent to the levitation module 410A. A given state estimation may define the position of the hyperloop vehicle 110 as well as the orientation of the hyperloop vehicle 110 at time t₁ (where the state estimation is generated at time t₀). To respond to the estimated state, the motion execution module 413A is configured to generate a plurality of commands to be distributed among the electromagnetic assemblies 227A, 228A, 229A. In a typical implementation, approximately sixty-four commands may need to be generated for the plurality of the PEUs 233N. A command may be related to a current value, a voltage value, an air gap value, a capacitive value, a force value, a directional force value, a rotational value, a flux density value, etc.

The generation of commands is non-trivial because magnetic field interactions are non-linear. Distance between an electromagnetic source and a material may greatly affect the field interactions within the material. Further, flux density within the material may increase the difficulty of estimating magnetic field interactions. In other words, the relationship between field strength and distance is non-linear. The motion execution module 413A utilizes sensor input and state estimation to generate a linearized plurality of commands to be sent to the electromagnetic assemblies 227A, 228A, 229A. Furthermore, a desired state in position and/or orientation may be achieved by a multitude of combinations of applied forces from the electromagnetic assemblies 227A, 228A, 229A (for instance). In addition to linearizing the non-linear force dynamics of the electromagnetic assemblies 227A, 228A, 229A, the motion execution module 413A generates the plurality of commands to the electromagnetic assembly (e.g., the electromagnetic assembly 227A) in order to minimize a secondary task such as minimal power draw, force generation, etc.

The sensor system 262 generally comprises a number of systems to provide input values to the hyperloop system 401. The sensor system 262 comprises an inertial measurement unit (“IMU”) system 262A and a laser gap sensor system 262B. The IMU system 262A is generally configured to calculate the orientation and/or position of the hyperloop vehicle 110. The laser gap sensor system 262B is generally configured to measure the air gap (e.g., the air gap 236A) between the electromagnetic assembly (e.g., the electromagnetic assembly 228A) and the rail (e.g., the rail 222). An example of the gap measurement may be the air gaps 236A, 236B, 236C, 236D, 236E.

The sensor module 415A is generally configured to gather data from the sensor system 262. For example, the sensor module 415A may receive laser gap measurement values from the laser gap sensor system 262B. For example, such measurements may be the air gaps 236A, 236B, 236C such that the electromagnetic assembly 228A may be commanded such that collision between the rail 222A and the electromagnetic assembly 228A is avoided. The sensor data is provided to the state estimation module 418A such that the state estimation module 418A generates a state estimation.

The state estimation module 418A is generally configured to generate a state estimation that represents a future orientation (i.e., roll, pitch, and yaw), a position (e.g., a fixed position as measured by the axes 214X, 214Y, 214Z), the rate of orientation (e.g., angular velocity), and/or the rate of position (e.g., linear velocity). The state estimation is utilized by the motion execution module 413A in order to generate a plurality of commands to position and orient the hyperloop vehicle 110 at a future time. Other commands may be utilized by the motion execution module 413A such as voltage values, air gap values, and/or force values.

The motion execution module 413A is designed such that one or more parameters are optimized and/or linearized. For instance, the motion execution module 413A may be designed to maximize power efficiency. However, excessive power efficiency optimization may lead to passenger discomfort. For instance, excessive power efficiency may cause undesirable amounts of jerk and/or acceleration which is directly linked to motion sickness in human passengers. To remedy these undesirable effects, the state estimation module 418A may be designed in tandem with the motion execution module 413A to consider additional parameters (such as passenger comfort) to generate a future state estimation that optimizes the parameters while avoiding undesirable situations. In other words, the performance of the motion execution module 413A is affected by the design of the state estimation module 418A.

The fault tolerance module 420A is generally configured to address fault conditions that occur within the hyperloop vehicle 110. For example, a state estimation may indicate that a collision is imminent. Another example may be where state estimation detects a sensor failure. For instance, the state estimation may account for the failure of the IMU system 262A such that other sensor systems may be utilized at a later time. Still another example may be where state estimation detects an engine failure. As such, the fault tolerance module 420A may invoke an emergency command that averts a collision (e.g., a command to apply braking force to the hyperloop vehicle 110).

A wayside communications module 423 is generally configured to communicate with the plurality of wayside transponders 109N. Communicated data may relate to any number of real-time conditions. For example, the communicated data may indicate that a downstream hyperloop vehicle is disabled. The hyperloop vehicle 110 may then determine the necessary commands to maintain the air gap (e.g., the air gap 236A) while an extreme braking scenario is required. In one aspect, the wayside communication module 423 may be configured to communicate via the high-speed network 111 to gather information. For instance, the high-speed network 111 may be utilized to indicate the presence of seismic activity that may affect a state estimation.

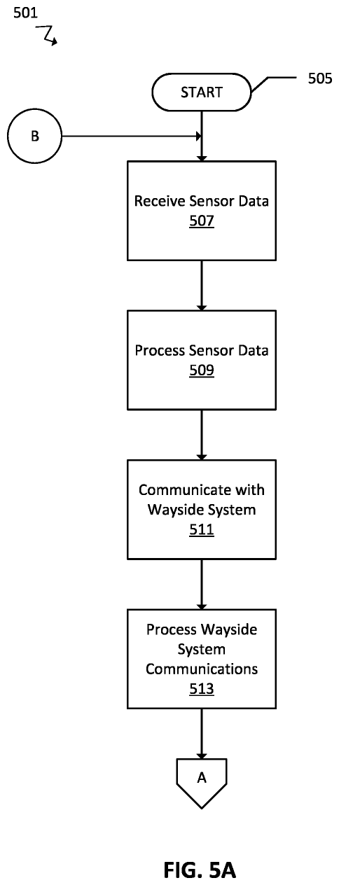

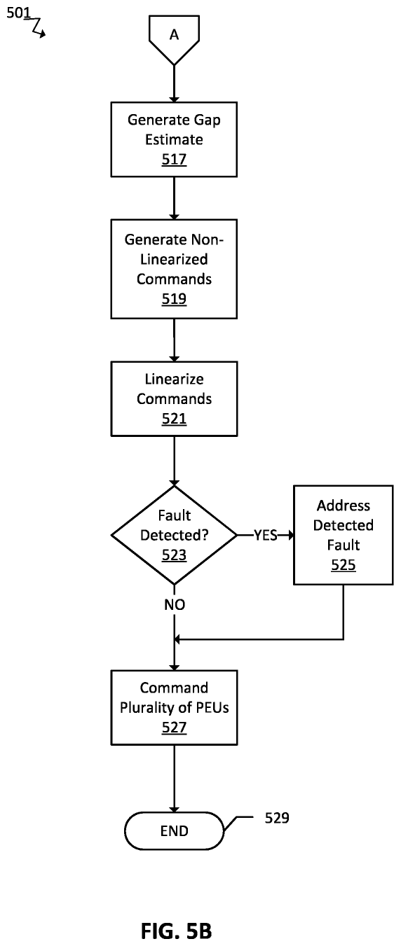

FIG. 5A is a flowchart depicting a process 501 for providing motion control and state estimation for the hyperloop vehicle 110 using the hyperloop system 401 described in FIG. 4 above. The process 501 begins at the start block 505 and proceeds to the block 507.

At the block 507, the process 501 receives sensor data. The process 501 utilizes the sensor module 415 in order to obtain measurements from the sensor system 262. For example, the process 501 may receive measurements (e.g., the air gaps 236A, 236B, 236C) from the laser gap sensor system 262B. Additional sensor systems within the sensor system 262 may be utilized by the sensor module 415 (as well as the process 501). The process 501 then proceeds to the block 509.

At the block 509, the process 501 processes the sensor data. In one aspect, the sensor data may be from a plurality of sensors. As such, the sensor module 415A may be required to fuse the received sensor data. For instance, the laser gap sensor system 262B may be a plurality of laser gap sensors, each of which are oriented at a different perspective such that the air gap (e.g., the air gap 236A) between the electromagnetic assembly 228A and the rail 222A may be reliably measured.

In one aspect, the process 501 may fuse together laser-based measurements with inertial-related measurements. Laser-based measurements generally provide geometric information (e.g., the air gaps 236A, 236B, 236C between the electromagnetic assembly 228A and the rail 222A). The IMU system 262A provides measurements to measure linear acceleration and angular velocities. In one aspect, the laser-gap sensor system 262B may provide more accurate measurements to measure the fast dynamics of the hyperloop vehicle 110 for use by the process 501. Further, the IMU system 262A provides more details about the position and/or orientation of the hyperloop vehicle 110 to the process 501; however, such details may be at longer intervals between measurements than those provided by the laser-gap sensor system 262B. As such, fusing the laser-based measurements with the IMU-based measurements provides a richer representation of the state of the hyperloop vehicle 110 for use by the process 501. The process 501 then proceeds to the block 511.

At the block 511, the process 501 communicates with the plurality of wayside transponders 109N. One of skill in the art will appreciate that the process 501 may communicate via the high-speed network 111 as well. The process 501 utilizes the wayside communication module 423 in order to communicate with the plurality of wayside transponders 109N. Data obtained from the plurality of wayside transponders 109N (and the high-speed network 111) is collectively referred to as wayside communication data. In one aspect, the plurality of wayside transponders 109N may communicate the position of a downstream hyperloop vehicle as the wayside communication data. In such a case, the plurality state estimation modules 418N may utilize such traffic data to augment a state estimation.

In another example, the wayside communication data may be directions to dock at a designated platform in a hyperloop portal—where state estimation and motion control would be just as applicable as during high-speed flight of the hyperloop vehicle 110. Therefore, the state estimation may incorporate not just position and/or orientation based on nearby measurements (as provided by the sensor system 262) but also system-wide information (e.g., stopped hyperloop vehicles affecting traffic flow, speed limits, portal navigation data, etc.). The process 501 then proceeds to the block 513.

At the block 513, the process 501 processes wayside communication data. The wayside communication data may have more than one message contained therein. As such, the communicated data is processed by the process 501 such that the proper system receives the necessary data at a desired time. For instance, laser-gap sensor information may be routed to the sensor modules 415N for processing. In one aspect, the processed wayside communication data may be augmented by additional data provided via the high-speed network 111. The process 501 then proceeds to the callout block A and resumes in FIG. 5B.

FIG. 5B is a flowchart depicting the process 501 for providing motion control and state estimation for the hyperloop vehicle 110 using the hyperloop system 401. The process 501 resumes at the callout block A and proceeds to the block 517.

At the block 517, the process 501 generates an air gap estimate. The air gap estimate generally relates to the position and/or orientation of the plurality of electromagnetic assemblies 279N with respect to the plurality of rails 221N. As shown in FIG. 3A through FIG. 3H, the air gaps 236A, 236B, 236C, 236D, 236E may deviate from the normative case depicted in said figures. For example, a current command sent to the PEU 230A at time t₀ may cause the electromagnetic assembly 228A to approach the rail 234A at time t₁. As such, the air gaps 236A may be less than a desired amount (e.g., fifteen millimeters). In such a case, the sensor system 262, by use of the laser gap sensor system 262B, may detect the reduction in air gap 236A in order to compensate at later time t₂. Likewise, in one aspect, the IMU system 262A may be utilized alone or in conjunction with the laser-based measurements.

One of skill in the art will appreciate that the plurality of PEUs 233N may have varying air gap distances that may require several measurements at varying angles, positions, and times. In one aspect, the various gap measurements (e.g., the air gap 236A) may be fused together in order to provide a comprehensive representation of the air gap measurements across the bogie assembly 220. Such fusion of the observed sensor data may be generated by the sensor system 262, the plurality of sensor modules 415N, and/or the plurality of state estimation modules 418N. The process 501 then proceeds to the block 519.

At the block 519, the process 501 generates non-linearized commands. The non-linearized commands generally relate to the amount of current, voltage, force, etc. to provide to the plurality of PEUs 233N (and the associated electromagnetic assemblies contained therein). For example, a current estimate may be a number of non-linearized values that may or may not consider the entirety of the plurality of PEUs 233N while in flight. One of skill in the art will appreciate that the non-linear nature of electromagnetic field interactions may require some linearization such that discrete commands relating to current, for instance, may be sent to the plurality of PEUs 233N.

While the process 501 may be explained as generating current-related commands, other similar commands may be generated. For instance, a voltage command may be sent which acts substantially similar to the current command. As with current, the voltage is subject to linearization by the process 501. Again, a command may be related to a current value, a voltage value, an air gap value, a capacitive value, a force value, a directional force value, a rotational value, a flux density target value, etc. Stated differently, the state estimation module 418A may generate non-linear commands with the data that is available at the time (e.g., sensor data). After the non-linear commands are generated, the linearization operations translate electromagnetic force to current. Any one of the command values may be translated to another type of value. For example, force may be linearized to capacitive value. Another example may be rotational value translated to current value. Such combinations proceed ad infinitum.

At the block 521, the process 501 linearizes the commands intended for the plurality of PEUs 233N. Given the relatively high number of PEUs present in an implementation of the hyperloop vehicle 110, the motion execution module 413 linearizes the current estimate generated at the block 219. The result of the linearization is a plurality of linearized commands being sent to the plurality of the PEUs 233N. In the example shown in FIG. 2A through FIG. 2C, the number of linearized commands is eight (i.e., one for each PEU within the plurality of PEUs 233A). However, a given PEU may have more than one electromagnetic assembly; therefore, the number of linearized commands may not be a one-to-one mapping of a command to a PEU. The process 501 then proceeds to the decision block 523.

At the decision block 523, the process 501 determines whether a fault has been detected. The process 501 may utilize the plurality of fault tolerance modules 420N in order to capture and/or report a fault to the proper system (e.g., the motion execution module 413A). For instance, a current command sent to the PEU 230A at time t₀ may not be adequately acted on and as such a fault may be detected at the fault tolerance module 420A. At time t₁, the fault tolerance module 420A will report the failure of the PEU 230A to the state estimation module 418 such that the next state estimation may consider the failure as part of the generation of a state estimation for a later time, e.g., at the time t₁. If a fault has been detected, the process 501 proceeds along the YES branch to the block 525.

At the block 525, the process 501 addresses the detected fault. In one aspect, as discussed, the state estimation module 418A may adjust a future state estimation. In another respect, the motion current module 413A may adjust the linearized current commands in order to address a potential fault that had been detected by the fault tolerance module 420A. Returning to the decision block 523, if a determination is made by the process 501 that a fault has not been detected, the process 501 proceeds along the NO branch to the block 527.

At the block 527, the process 501 commands the plurality of PEUs 233N. In one aspect, the process 501 may send a plurality of linearized current values to the plurality of PEUs 233N in the form of discrete values that are based on the commands sent to the remainder of the plurality of PEUs 233N. For example, in the event that any of the commands result in a fault, the fault tolerance module 420A may detect such a fault and then communicate the fault via the link 425A to the state estimation module 418A and/or the motion execution module 413A. The process 501 then proceeds to the end block 529 and terminates.

As shown, a Reference B is denoted to indicate that the process 501 is iterative, in one aspect. State estimation and motion control are generally an ongoing process while the hyperloop vehicle 110 is in flight. In other words, the hyperloop system 401 is generally configured to provide many state estimations over time. As such, previous state estimations may inform future state estimations. Further, previous motion control commands may inform subsequent operations of the process 501.

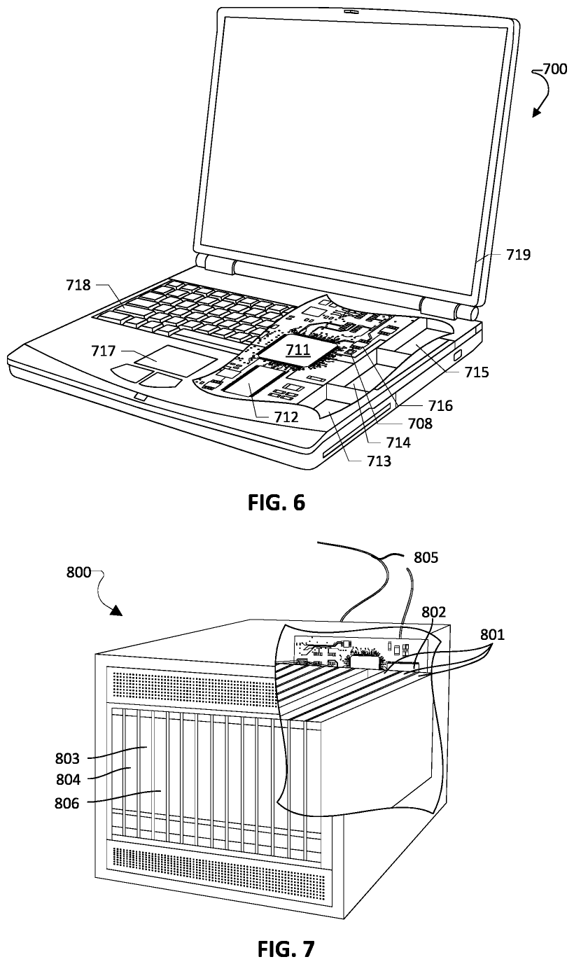

FIG. 6 is a block diagram illustrating a computing device 700 suitable for use with the various aspects described herein. In one aspect, the computing device 700 may be configured to store and execute the hyperloop system 401 and the process 501. In one aspect, the computing device 700 may embody the processor 402 and the memory 403.

The computing device 700 may include a processor 711 (e.g., an ARM processor) coupled to volatile memory 712 (e.g., DRAM) and a large capacity nonvolatile memory 713 (e.g., a flash device). Additionally, the computing device 700 may have one or more antenna 708 for sending and receiving electromagnetic radiation that may be connected to a wireless data link and/or cellular telephone transceiver 716 coupled to the processor 711. The computing device 700 may also include an optical drive 714 and/or a removable disk drive 715 (e.g., removable flash memory) coupled to the processor 711.

The computing device 700 may include a touchpad touch surface 717 that serves as the computing device's 700 pointing device, and thus may receive drag, scroll, flick etc. gestures similar to those implemented on computing devices equipped with a touch screen display as described above. In one aspect, the touch surface 717 may be integrated into one of the computing device's 700 components (e.g., the display). In one aspect, the computing device 700 may include a keyboard 718 which is operable to accept user input via one or more keys within the keyboard 718. In one configuration, the computing device's 700 housing includes the touchpad 717, the keyboard 718, and the display 719 all coupled to the processor 711. Other configurations of the computing device 700 may include a computer mouse coupled to the processor (e.g., via a USB input) as are well known, which may also be used in conjunction with the various aspects described herein.

FIG. 7 is a block diagram illustrating a server 800 suitable for use with the various aspects described herein. In one aspect, the server 800 may be configured to store and execute the hyperloop system 401 and the process 501. In one aspect, the server 800 may embody the processor 402 and the memory 403.

The server 800 may include one or more processor assemblies 801 (e.g., an x86 processor) coupled to volatile memory 802 (e.g., DRAM) and a large capacity nonvolatile memory 804 (e.g., a magnetic disk drive, a flash disk drive, etc.). As illustrated in instant figure, processor assemblies 801 may be added to the server 800 by insertion into the racks of the assembly. The server 800 may also include an optical drive 806 coupled to the processor 801. The server 800 may also include a network access interface 803 (e.g., an ethernet card, WIFI card, etc.) coupled to the processor assemblies 801 for establishing network interface connections with a network 805. The network 805 may be a local area network, the Internet, the public switched telephone network, and/or a cellular data network (e.g., LTE, 5G, etc.).

The foregoing method descriptions and diagrams/figures are provided merely as illustrative examples and are not intended to require or imply that the operations of various aspects must be performed in the order presented. As will be appreciated by one of skill in the art, the order of operations in the aspects described herein may be performed in any order. Words such as “thereafter,” “then,” “next,” etc. are not intended to limit the order of the operations; such words are used to guide the reader through the description of the methods and systems described herein. Further, any reference to claim elements in the singular, for example, using the articles “a,” “an,” or “the” is not to be construed as limiting the element to the singular.

Various illustrative logical blocks, modules, components, circuits, and algorithm operations described in connection with the aspects described herein may be implemented as electronic hardware, computer software, or combinations of both. To clearly illustrate this interchangeability of hardware and software, various illustrative components, blocks, modules, circuits, operations, etc. have been described herein generally in terms of their functionality. Whether such functionality is implemented as hardware or software depends upon the particular application and design constraints imposed on the overall system. One of skill in the art may implement the described functionality in varying ways for each particular application, but such implementation decisions should not be interpreted as causing a departure from the scope of the claims.

The hardware used to implement various illustrative logics, logical blocks, modules, components, circuits, etc. described in connection with the aspects described herein may be implemented or performed with a general purpose processor, a digital signal processor (“DSP”), an application specific integrated circuit (“ASIC”), a field programmable gate array (“FPGA”) or other programmable logic device, discrete gate logic, transistor logic, discrete hardware components, or any combination thereof designed to perform the functions described herein. A general-purpose processor may be a microprocessor, a controller, a microcontroller, a state machine, etc. A processor may also be implemented as a combination of receiver smart objects, e.g., a combination of a DSP and a microprocessor, a plurality of microprocessors, one or more microprocessors in conjunction with a DSP core, or any other such like configuration. Alternatively, some operations or methods may be performed by circuitry that is specific to a given function.

In one or more aspects, the functions described may be implemented in hardware, software, firmware, or any combination thereof. If implemented in software, the functions may be stored as one or more instructions (or code) on a non-transitory computer-readable storage medium or a non-transitory processor-readable storage medium. The operations of a method or algorithm disclosed herein may be embodied in a processor-executable software module or as processor-executable instructions, both of which may reside on a non-transitory computer-readable or processor-readable storage medium. Non-transitory computer-readable or processor-readable storage media may be any storage media that may be accessed by a computer or a processor (e.g., RAM, flash, etc.). By way of example but not limitation, such non-transitory computer-readable or processor-readable storage media may include RAM, ROM, EEPROM, NAND FLASH, NOR FLASH, M-RAM, P-RAM, R-RAM, CD-ROM, DVD, magnetic disk storage, magnetic storage smart objects, or any other medium that may be used to store program code in the form of instructions or data structures and that may be accessed by a computer. Disk as used herein may refer to magnetic or non-magnetic storage operable to store instructions or code. Disc refers to any optical disc operable to store instructions or code. Combinations of any of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

The preceding description of the disclosed aspects is provided to enable any person skilled in the art to make, implement, or use the claims. Various modifications to these aspects will be readily apparent to those skilled in the art, and the generic principles defined herein may be applied to other aspects without departing from the scope of the claims. Thus, the present disclosure is not intended to be limited to the aspects illustrated herein but is to be accorded the widest scope consistent with the claims disclosed herein.

1. A method for state estimation to provide motion control of a hyperloop vehicle, the method comprising:
receiving, at a processor, sensor data, the sensor data providing a plurality of air gap distances between a plurality of electromagnetic assemblies and a plurality of rails, the plurality of electromagnetic assemblies being associated with a plurality of power electronic units, respectively;
generating, at the processor, a state estimation, the state estimation being generated at a first time and comprising a position of the hyperloop vehicle at a second time and an orientation of the hyperloop vehicle at the second time, the second time being subsequent to the first time;
generating, at the processor, a plurality of non-linearized commands associated with the state estimation, the non-linearized commands being configured to position and orient the plurality of electromagnetic assemblies with respect to the plurality of rails;
linearizing the plurality of non-linearized commands to generate a plurality of linearized commands, the plurality of linearized commands being configured for the plurality of power electronic units to control a plurality of electromagnetic fields generated at the plurality of electromagnetic assemblies; and
distributing the linearized commands within the plurality of power electronic units.

2. The method of claim 1, wherein the sensor data is obtained from an inertial measurement unit system, a laser gap sensor system, or a combination thereof, further wherein the sensor data is fused.

3. The method of claim 1, wherein the sensor data further comprises wayside communication data received from a wayside communication module, the wayside communication module being in communication with a plurality of transponders, a high-speed network, or a combination thereof.

4. The method of claim 1, wherein the command is associated with a current value, a voltage value, an electromagnetic force value, an air gap value, or a combination thereof.

5. The method of claim 1, wherein the state estimation further comprises a rate of change of position of the hyperloop vehicle, a rate of change of orientation of the hyperloop vehicle, or a combination thereof.

6. The method of claim 1, further comprising:
detecting, at the processor, a fault at the plurality of power electronic units, the plurality of electromagnetic assemblies, or a combination thereof; and
updating the state estimation based on the detected fault.

7. A hyperloop system configured to generate a state estimation configured to provide motion control for a hyperloop vehicle, the hyperloop system comprising:
a plurality of power electronic units comprising a plurality of electromagnetic assemblies, respectively;
a memory; and
a processor, the processor configured to:
receive sensor data, the sensor data providing a plurality of air gap distances between the plurality of electromagnetic assemblies and a plurality of rails;
generate a state estimation, the state estimation being generated at a first time and comprising a position of the hyperloop vehicle at a second time and an orientation of the hyperloop vehicle at the second time, the second time being subsequent to the first time;
generate a plurality of non-linearized commands being associated with the state estimation, the non-linearized commands being configured to position and orient the plurality of electromagnetic assemblies with respect to the plurality of rails;
linearize the plurality of non-linearized commands to generate a plurality of linearized commands, the plurality of linearized commands being configured for the plurality of power electronic units to control a plurality of electromagnetic fields generated at the plurality of electromagnetic assemblies; and
distribute the linearized commands within the plurality of power electronic units.

8. The hyperloop system of claim 7, wherein the sensor data is obtained from an inertial measurement unit system, a laser gap sensor, or a combination thereof, further wherein the sensor data is fused.

9. The hyperloop system of claim 7, wherein the sensor data further comprises wayside communication data received from a wayside communication module, the wayside communication module being in communication with a plurality of transponders, a high-speed network, or a combination thereof.

10. The hyperloop system of claim 7, wherein the command is associated with a current value, a voltage value, an electromagnetic force value, or a combination thereof.

11. The hyperloop system of claim 7, wherein the state estimation further comprises a rate of change of position of the hyperloop vehicle, a rate of change of orientation of the hyperloop vehicle, or a combination thereof.

12. The hyperloop system of claim 7, the processor being further configured to:
detect a fault at the plurality of power electronic units, the plurality of electromagnetic assemblies, or a combination thereof; and
update the state estimation based on the detected fault.

13. A method for motion control execution based on a state estimation of a hyperloop vehicle, the method comprising:
generating, at a processor, a state estimation at a first time, the state estimation being based on a plurality of non-linearized commands for a plurality of power electronic units, the state estimation further being associated with a second time, the second time being subsequent to the first time;
processing, at the processor, the plurality of non-linearized commands to generate a plurality of linearized commands, the plurality of linearized commands being configured to position and orient the hyperloop vehicle according to the state estimation; and
sending, at the processor, the plurality of linearized commands to a plurality of power electronic units.

14. The method of claim 13, wherein the plurality of linearized commands is associated with a current value, an air gap value, a voltage value, an electromagnetic force value, or a combination thereof.

15. The method of claim 13, the method further comprising:
detecting, at the processor, a fault; and
updating, at the processor, the linearized commands to address the fault.

16. The method of claim 13, wherein the plurality of linearized commands is configured as input to a subsequent state estimation.

17. A hyperloop system configured to provide motion control to a hyperloop vehicle, the hyperloop system comprising:
a plurality of power electronic units being associated with a plurality of electromagnetic assemblies, respectively;
a memory; and
a processor, the processor configured to:
generate a state estimation at a first time, the state estimation being based on a plurality of non-linearized commands for a plurality of power electronic units, the state estimation further being associated with a second time, the second time being subsequent to the first time;
process the plurality of non-linearized commands to generate a plurality of linearized commands, the plurality of linearized commands being configured to position and orient the hyperloop vehicle according to the state estimation; and
send the plurality of linearized commands to a plurality of power electronic units.

18. The hyperloop system of claim 17, wherein the plurality of linearized commands is associated with a current value, an air gap value, a voltage value, an electromagnetic force value, or a combination thereof.

19. The hyperloop system of claim 17, the processor being further configured to:
detect a fault; and
update the linearized commands to address the fault.

20. The hyperloop system of claim 17, wherein the plurality of linearized commands is configured as input to a subsequent state estimation.
